(19) United States
(12) Patent Application Publication
(10) Pub. No.: US 2019/0296216 A1
(43) Pub. Date: Sep. 26, 2019

(54) TRANSPARENT PIEZOELECTRIC DEVICE AND METHOD FOR MANUFACTURING THE SAME

(71) Applicant: Luxembourg Institute Of Science And Technology (LIST), Esch-sur-Alzette (LU)

(72) Inventors: Daniele Sette, Audun-le-Tiche (FR); Emmanuel Defay, Luxembourg (LU)

(21) Appl. No.: 16/304,503

(22) PCT Filed: May 16, 2017
(86) PCT No.: PCT/EP2017/061757

§ 371 Date: Nov. 26, 2018

(30) Foreign Application Priority Data
May 24, 2016 (LU) LU93084

(51) Int. Cl. H01L 41/047; H01L 41/09; H01L 41/113; H01L 41/187; H01L 41/29; H01L 41/318

(52) U.S. Cl. CPC H01L 41/0478; H01L 41/0986; H01L 41/318; H01L 41/1876; H01L 41/29; H01L 41/1132

(57) ABSTRACT

The invention is directed to a transparent piezoelectric device comprising a transparent substrate; a transparent piezoelectric layer; a transparent layer of interdigitated electrodes. The transparent piezoelectric layer is disposed between the substrate and the layer of interdigitated electrodes.

### CROSS-REFERENCE TO RELATED APPLICATIONS

The present invention is the U.S. national stage under 35 U.S.C. §371 of International Application No. PCT/EP2017/061757, which was filed on May 16, 2017, and which claims the priority of application LU 93084 filed on May 24, 2016, the content of which (text, drawings and claims) are incorporated here by reference in its entirety.

### FIELD

The invention is directed to a transparent piezoelectric device. The invention is also directed to a method for producing a transparent piezoelectric device.

### BACKGROUND

Transparent piezoelectric devices usually have a Metal-Insulator-Metal (MIM) structure. They comprise a transparent substrate and a transparent piezoelectric layer, said piezoelectric layer being comprised between two transparent layers of electrodes, as it is described in the patent document published WO/2013164540. However, these devices are massive and present high probabilities of short-circuit.

Prior art patent document published CN105185898 discloses a transparent and flexible piezoelectric device. The device comprises a mica layer on which a layer of electrodes is disposed. The layer of electrodes is transparent and consists of interdigitated electrodes. The layer of electrodes is then covered by piezoelectric materials consisting of nanowires of Lead Zirconate Titanate (PZT). The device also comprises two protective layers which are bonded to the upper and lower sides of the electrode layer. However, the device is flexible and miniature. The interdigitated electrodes are formed on a mica substrate which has then to be thinned. The piezoelectric layer consists of nanowires which have to be bounded or mixed with the interdigitated electrodes. Moreover, the contact of the piezoelectric material is heterogeneous because the PZT nanowires are deposited on the electrodes and on the mica substrate. The method of depositing the piezoelectric layer does not allow to have a homogeneous piezoelectric layer. The device presents insufficient contact between the PZT nanowires and the layer of electrodes

### SUMMARY

The invention has for technical problem to provide a solution to at least one shortcoming of the prior art. More particularly, the invention has for technical problem to provide a transparent piezoelectric device on a transparent substrate. The invention has also for technical problem to provide a time and cost effective method of production.

The invention is directed to a transparent piezoelectric device comprising a transparent substrate, a transparent piezoelectric layer, a transparent layer of interdigitated electrodes; wherein the piezoelectric layer is disposed between the substrate and the layer of interdigitated electrodes.

According to various embodiments, the transparent piezoelectric layer is a uniform deposited layer.

According to various embodiments, the transparent layer of interdigitated electrodes comprises two coplanar electrodes, each electrode having a plurality of fingers which are interdigitated.

According to various embodiments, the piezoelectric layer covers at least 10% of the surface of the transparent substrate, preferably at least 50%, more preferably at least 70%.

According to various embodiments, the transparent layer of electrodes comprises a conductive transparent metal oxide.

According to various embodiments, the device further comprises a transparent dielectric layer between the substrate and the piezoelectric layer.

According to various embodiments, the substrate is a fused silica wafer.

According to various embodiments, the substrate is a glass substrate.

According to various embodiments, the piezoelectric layer has a thickness of less than 10 μm, preferably higher than 0.1 μm and/or lower than 2 μm.

According to various embodiments, the dielectric layer has a thickness comprised between 1 and 30 nm, preferably higher than 1 and/or lower than 20 nm.

The invention is also directed to a method for producing a transparent piezoelectric device, the method comprising the following steps of providing a transparent substrate; depositing a transparent piezoelectric layer on the transparent substrate; depositing a transparent layer of interdigitated electrodes on the transparent substrate; wherein the step of depositing a transparent piezoelectric layer is performed before the step of depositing a transparent layer of interdigitated electrodes.

According to various embodiments, the method further comprises a step of depositing a transparent dielectric layer on the transparent substrate before the step of depositing a transparent piezoelectric layer on the transparent substrate.

According to various embodiments, the step of depositing a transparent piezoelectric layer is performed by spin coating and a sol-gel method.

According to various embodiments, the step of depositing a transparent layer of interdigitated electrodes is performed by atomic layer deposition and lift-off lithography, and/or lithography and etching.

According to various embodiments, the sol-gel method comprises the following sequential steps of drying; pyrolizing; and crystallizing.

According to various embodiments, the spin coating and the steps of drying and pyrolizing are repeated 3 times.

The invention is particularly interesting in that the device presents a good contact between the piezoelectric layer and the layer of electrodes because of the conformal deposition of electrodes on the piezoelectric layer. The coplanar deposition of the electrodes on the piezoelectric layer allows avoiding short-circuits. The configuration of the device also provides a good optimization of the piezoelectric material. The method allows a conformal deposition of the piezoelectric layer on transparent and rigid substrates and the formation of piezoelectric device on large area. The method also provides a time and cost effective solution to produce a transparent piezoelectric device.

### DRAWINGS

FIG. 1 shows a top view of the device according to various embodiments of the invention.

FIG. 2 represents a cross-section of the device according to FIG. 1, according to various embodiments of the invention.

FIG. 3 shows the evolution of the electric displacement (μC/cm²) of the device according to a bias voltage (V), according to various embodiments of the invention.

FIG. 4 shows the evolution of the capacitance (pF) and the loss factor tan (δ) according to a bias voltage (V), according to various embodiments of the invention.

FIG. 5 is a flowchart showing the major steps of the method according to various embodiments of the invention.

### DETAILED DESCRIPTION

In the following description the term “transparent” is used to mean that a material or a device transmits at least 40%, for example at least 70%, in various instances at least 90% of the incident visible light.

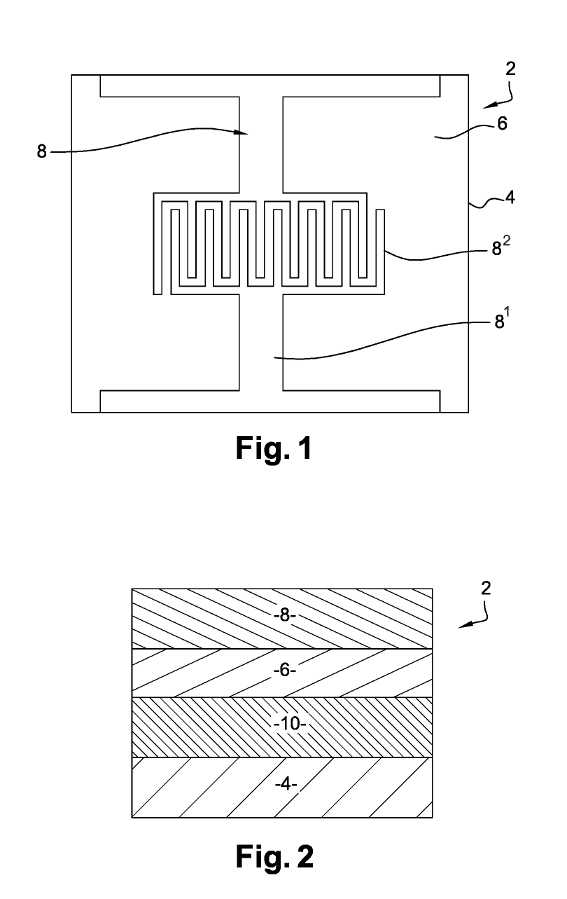

FIG. 1 represents the piezoelectric device 2 according to the invention. The device 2 comprises a transparent substrate 4 (not visible in FIG. 1), a transparent piezoelectric layer 6 and a transparent layer 8 of interdigitated electrodes. The piezoelectric layer 6 is disposed between the substrate 4 and the layer 8 of interdigitated electrodes. The transparent piezoelectric layer 6 is a uniform deposited layer of piezoelectric materials or a continuous film of piezoelectric materials. The piezoelectric layer does not contain nanowires, nanorods, nanospheres or the like. The piezoelectric layer in various instances comprises PZT. (Pb,La)(Zr,Ti)O₃, Pb(Mg,Nb)TiO₃-PbTiO₃, BiFeO₃, (Ba,Ca)(Ti,Zr)O_{3+,} AlN, Sc doped-AlN, ZnO, LiNbO₃ can also be used. The layer 8 of interdigitated electrodes can comprise two coplanar electrodes 8¹. The two electrodes 8¹ are opposite electrodes and each of the electrodes can comprise a plurality of fingers 8², for example between 5 and 10, in various instances 7, which are alternated and spaced between them. The two electrodes 8¹ can have the form of two interdigitated combs. Each finger 8² has a width comprised between 1 and 50 μm, in various instances 10 μm. The fingers 8² can be spaced from each other with a gap or an interdigital space comprised between 1 and 50 μm. The fingers can have a length comprised between 10 and 10000 μm, for example 50 μm. The form of the electrodes is not limiting and the electrodes can have other form. For example, they can be semi-circular. By the below method, it will be seen that the dimensions of the device including the dimensions and the numbers of the fingers of the electrodes can vary.

The layer 8 of interdigitated electrodes comprises a transparent metal oxide. In various embodiments, the transparent layer 8 of interdigitated electrodes comprise Al-doped ZnO (AZO). Indium Tin Oxide (ITO), RuO₂ or IrO₂ can also be used.

The piezoelectric layer 6 covers at least 10% of the surface of the transparent substrate 4, for example at least 50%, in various instances at least 70% of the surface of the substrate.

The device 2 transmits at least 40%, for example at least 70%, in various instances 90% of the incident visible light. The device 2 can have wide applications. The device 2 can be used as a sensor, an actuator or in energy harvesting or in others applications. The device has a piezoelectric actuation mode d33, which corresponds to the longitudinal piezoelectric strain coefficient.

FIG. 2 is a cross sectional view of the device according to FIG. 1. The device 2 comprises the transparent substrate 4 at the bottom. The substrate 4 can be a fused silica wafer. The transparent piezoelectric layer 6 is above the substrate 4 and is disposed between the substrate 4 and the transparent layer 8 of interdigitated electrodes. The transparent piezoelectric layer 6 has a thickness of less than 10 μm, for example higher than 0.1 μm and/or lower than 2 μm. The transparent layer 8 of interdigitated electrodes has a thickness comprised between 20 nm and 10 μm, for example comprised between 100 nm and 1 μm.

The device 2 can also comprise a transparent dielectric layer 10 between the substrate 4 and the transparent piezoelectric layer 6. The dielectric layer 10 has a thickness comprised between 5 and 30 nm, for example higher than 5 and/or lower than 20 nm. The dielectric layer is in various instances a layer of TiO_{2.} ZrO₂, Al₂O₃ or the like, HfO₂, AlN, PbTiO₃, PbZrO₃, BiFeO₃, PbO, Y₂O₃, CeO₂ can also be used to form the dielectric layer. The device 2 can also comprise a protective transparent layer above the transparent layer of electrodes.

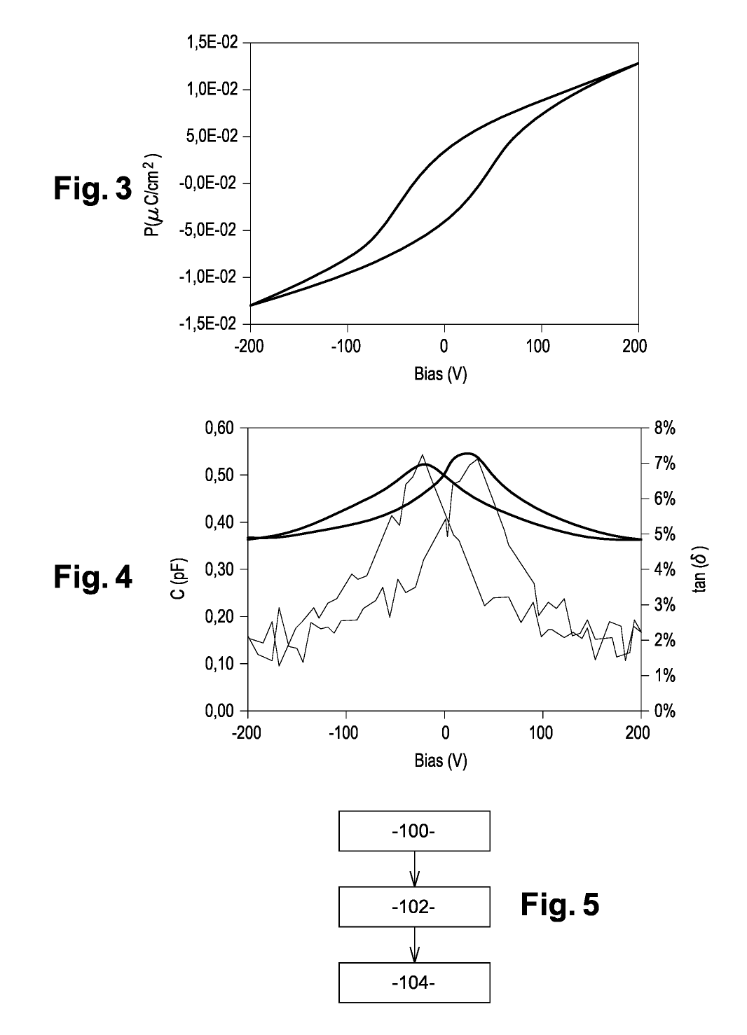

The piezoelectric device according to the invention has been tested in order to control its performance. More particularly, the device under tests comprises 2 electrodes with 7 fingers, each finger having a length of 50 μm, a width of 10 μm and a gap or interdigital space of 5 μm. The piezoelectric layer is made of PZT, the electrodes are in AZO and the dielectric layer is made of TiO₂. The piezoelectric device has been submitted to a bias voltage. The results are represented in FIG. 3 which shows a graphic of the electric displacement field P(μC/cm₂) according to the bias (V). The bias (V) represents the external electrical field applied to the piezoelectric material of the device. The graphic shows a hysteresis cycle. The hysteretic behaviour is characteristic of ferroelectric materials.

FIG. 4 shows the evolution of the capacitance (pF) and the dielectric loss (tan (δ)) according to a bias voltage (V). The piezoelectric device has small losses, thanks to its in-plane configuration.

FIG. 5 is a flowchart showing the major steps of the method for producing a transparent piezoelectric device according to the invention. The method comprises a step 100 of providing a transparent substrate, a step 102 of depositing a transparent piezoelectric layer on the transparent substrate and a step 104 of depositing a transparent layer of interdigitated electrodes on the transparent substrate. The step 102 of depositing a transparent piezoelectric layer is performed before the step 104 of depositing the transparent layer of interdigitated electrodes.

The method can further comprise a step of depositing a transparent dielectric layer on the transparent substrate before the step of depositing a transparent piezoelectric layer. The dielectric layer can be used as a nucleation or buffer layer for the growth of the piezoelectric layer. The dielectric layer can be performed by evaporation of 20 nm of titanium followed by a thermal oxidation at 700° C. during 30 min in air.

The step of depositing a transparent piezoelectric layer can be performed by spin coating and a sol gel method.

A spin coating was performed by first depositing a PZT precursor solution on the substrate. Then, the substrate was sequentially rotated during 20 s at 20 rpm, then at 3600 rpm during 0.5 s and at 1800 rpm during 30 s.

After spin coating, a sol gel method was performed. A first step of drying was performed. The step of drying comprises a first annealing. A hot plate was used at 130° C. during 5 min. A pyrolysis step was then performed. A second annealing was performed with an oven in air at 350° C. during 5 min in order to break the metal-organic precursor and burn the organic compounds.

The steps of spin coating, drying and pyrolysis are repeated 3 times. A crystallization step was then performed. Annealing was performed with an oven in air at 700° C. during 5 min in order to crystallize the solid solution. The annealing can also be performed with a rapid thermal annealing process.

The step of depositing a transparent piezoelectric layer can also be performed by sputtering, MOCVD or pulsed laser deposition.

The step of depositing the transparent layer of interdigitated electrodes can be performed by atomic layer deposition of a transparent conductive metal and a process of lift-off lithography or by a standard lithography process followed by etching. More particularly, the transparent conductive layer deposited by the method of atomic layer deposition comprises a transparent metal oxide, for example Al-doped ZnO, Indium Tin Oxide (ITO), RuO₂ or IrO₂. The materials can also be deposited by sputtering or evaporation instead of an atomic layer deposition method. In the case of ITO or AZO, a sol-gel process can be also performed.

The method can be used to produce a transparent piezoelectric device according to the invention with an active area higher than 1 cm². For example, the method can be used to produce the device with an active area of 100 cm².

1.-14. (canceled)

15. A transparent piezoelectric device, said device comprising:
a transparent substrate;
a transparent piezoelectric layer;
a transparent layer of interdigitated electrodes, the piezoelectric layer being disposed between the substrate and the layer of interdigitated electrodes; and
a transparent dielectric layer between the substrate and the piezoelectric layer, the dielectric layer having a thickness comprised between 1 nm and 30 nm.

16. The device according to claim 15, wherein the transparent piezoelectric layer is a uniform deposited layer.

17. The device according to claim 15, wherein the transparent layer of interdigitated electrodes comprises two coplanar electrodes, each electrode having a plurality of fingers which are interdigitated.

18. The device according to claim 15, wherein the piezoelectric layer covers at least 10% of the surface of the transparent substrate.

19. The device according to claim 15, wherein the piezoelectric layer covers at least 50% of the surface of the transparent substrate.

20. The device according to claim 15, wherein the piezoelectric layer covers at least 70% of the surface of the transparent substrate.

21. The device according to claim 15, wherein the transparent layer of electrodes comprises a conductive transparent metal oxide.

22. The device according to claim 15, wherein the substrate is one of a fused silica wafer or a glass substrate.

23. The device according to claim 15, wherein the piezoelectric layer has a thickness of less than 10 μm.

24. The device according to claim 15, wherein the piezoelectric layer has a thickness that is at least one of higher than 0.1 μm and lower than 2 μm.

25. The device according to claim 15, wherein the dielectric layer has a thickness lower than 20 nm.

26. A method for producing a transparent piezoelectric device, said method comprising the following steps of:
providing a transparent substrate;
depositing a transparent piezoelectric layer on the transparent substrate;
depositing a transparent layer of interdigitated electrodes on the transparent substrate, wherein the step of depositing a transparent piezoelectric layer is performed before the step of depositing a transparent layer of interdigitated electrodes; and
depositing a transparent dielectric layer on the transparent substrate before the step of depositing a transparent piezoelectric layer on the transparent substrate, the dielectric layer having a thickness comprised between 1 and 30 nm.

27. The method according to claim 26, wherein the transparent piezoelectric device comprises:
a transparent substrate;
a transparent piezoelectric layer;
a transparent layer of interdigitated electrodes, the piezoelectric layer being disposed between the substrate and the layer of interdigitated electrodes; and
a transparent dielectric layer between the substrate and the piezoelectric layer, the dielectric layer having a thickness comprised between 1 and 30 nm.

28. The method according to claim 26, wherein the step of depositing a transparent piezoelectric layer is performed by spin coating and a sol-gel method.

29. The method according to claim 26, wherein the step of depositing a transparent layer of interdigitated electrodes is performed by at least one of atomic layer deposition, lift-off lithography, and lithography and etching.

30. The method according to claim 28, wherein the sol-gel method comprises the following sequential steps of:
drying;
pyrolizing; and
crystallizing.

31. The method according to claim 30, wherein the spin coating and the steps of drying and pyrolizing are repeated 3 times.
